(19) United States
(12) Patent Application Publication
(10) Pub. No.: US 2008/0117083 A1
(43) Pub. Date: May 22, 2008

(54) Magnetic encoder

(76) Inventor: Hideo MIZUTA, Okayama (JP)

Correspondence Address: WENDEROTH, LIND & PONACK, L.L.P., 2033 K STREET N. W., SUITE 800, WASHINGTON, DC, 20006-1021, US

(21) Appl. No.: 11/976,537

(22) Filed: Oct. 25, 2007

Related U.S. Application Data
(63) Continuation of application No. 11/701,355, filed on Feb. 2, 2007, now abandoned.
Application No. 11/701,355 is a continuation of application No. 10/621,310, filed on Jul. 18, 2003, now abandoned.

(30) Foreign Application Priority Data
Jul. 19, 2002 (JP) 2002-211157

(51) Int. Cl. H03M 1/22

(52) U.S. Cl. 341/15

(57) ABSTRACT

A magnetic encoder for use in a wheel bearing that forms a pulse train by means of a magnetic force and generates a code. The magnetic encoder is obtained by radially magnetizing a magnetic rubber ring with alternate S poles and N poles, said magnetic rubber ring is formed by vulcanizing and adhering a magnetic rubber base, in which unvulcanized rubber and rare earth magnetic powder are mixed, to a reinforcement ring.

This application is a continuation of application Ser. No. 11/701,355, filed Feb. 2, 2007, which is a continuation of application Ser. No. 10/621,310, filed Jul. 18, 2003.

### BACKGROUND OF THE INVENTION

1. Field of the Invention

The present invention relates to a magnetic encoder that is used in a wheel bearing, forms a pulse train by means of a magnetic force and generates codes. In particular, the present invention relates to a magnetic encoder that has strong magnetic force characteristics, and is excellent in the rubber elasticity and advantageous in productivity and price.

2. Description of Prior Art

A magnetic encoder that is used in a wheel bearing, forms a pulse train by means of a magnetic force and generates codes has been made of a rubber material having magnetic properties. In the magnetic encoder made of the rubber material that has the magnetic properties, as the rubber material, for instance, natural rubber, nitrile rubber, hydrogenated nitrile rubber, butyl rubber, fluororubber or acrylic rubber is used. The rubber material is mixed with magnetic powder and a desired rubber chemical, heated and pressurized in a mold, and thereby vulcanized and formed into a desired shape.

As the magnetic powder used here, in general, ferrite powder is adopted. Rare earth magnetic materials, being poor in the kneading workability and the formability and high in the cost, have been considered unsuitable to mix with the rubber material and have not been adopted in forming the magnetic encoder.

The magnetic force of the encoder that uses ferrite as the magnetic powder, although it is excellent in the formability, is small. And the dispersion of the magnetic flux density of the encoder that uses ferrite as the magnetic powder is large, since the magnetic powder of ferrite has an orientation.

In order to reduce the dispersion, there is developed a method in which a magnetic encoder is formed in a magnetic field. However, in the surroundings of a metal mold, a coil is necessary to generate a magnetic field.

In a magnetic encoder that uses ferrite powder as the magnetic powder, as mentioned above, the magnetic force is small; accordingly, in order to endow with practical magnetic characteristics, the ferrite has to be packed in high density. However, when the ferrite is densely packed, physical properties of the rubber deteriorate largely.

Furthermore, in order suppress the magnetic flux density from largely dispersing along a periphery of the encoder, troublesome methods such as blending various kinds of ferrites or increasing formation steps are necessary.

### SUMMARY OF THE INVENTION

An object of the present invention is to overcome problems present in the existing magnetic encoders that use the ferrite powder as the magnetic powder and to provide magnetic encoder having strong magnetic characteristics, and is excellent in the formability, and realizable even in view of price.

Present inventors, after studying variously of magnetic encoders that use rare earth magnetic material and conducting tests of the magnetic characteristics, found a magnetic encoder that has strong magnetic characteristics, is excellent in the formability and is realizable also from a viewpoint of price.

The present invention will be explained with reference to attached drawings. The magnetic encoder according to the invention, as shown in FIGS. 1, 2 and 3, can be used in a wheel bearing (not shown in the drawing), forms a pulse train by means of a magnetic force and generates codes.

The magnetic encoder according to the invention is formed by radially magnetizing a magnetic rubber ring 2 with alternate S poles and N poles, said magnetic rubber ring 2 is formed by mixing a rubber material and magnetic powder, wherein rare earth magnetic powder is used as the said magnetic powder.

Another magnetic encoder according to the invention is obtained by radially magnetizing a magnetic rubber ring 2 with alternate S poles and N poles, said magnetic rubber ring 2 is formed by vulcanizing and adhering a magnetic rubber base (not shown in the drawing) to a reinforcement ring 1, wherein the magnetic rubber base is formed by mixing unvulcanized rubber and rare earth magnetic powder.

All of the magnetic encoders according to the invention, because of the strength of the magnetic force, become a multi-pole magnet having a large number of poles.

In the above, the magnetic rubber ring 2 has preferably a thickness in the range of from 0.2 to 2.0 mm expressed as a length in an up and down direction in a sectional view shown in FIG. 2. Furthermore, a width dimension of the magnetic rubber ring 2 that is represented with a length in a horizontal direction in a sectional view of FIG. 2 and represented with a dimension in a radial direction in a perspective view of FIG. 1 is sufficient to be substantially in the range of from 1.0 to 3.0 mm.

In the magnetic encoder according to the invention, rare earth magnetic powder is used; accordingly, with such a small size, a magnetic force necessary for the magnetic encoder that can be used in a wheel bearing, forms a pulse train by means of the magnetic force and generates codes can be obtained. Thereby, a magnetic encoder can be made smaller in size and lighter in weight.

Although the above size can sufficiently exhibit the magnetic force necessary for the magnetic encoder, it is without saying that the width dimension can be made larger than 3.0 mm in compliance with a portion where the magnetic encoder according to the invention is adopted.

As the rubber material, similarly to the case of the existing magnetic encoder where the ferrite powder is used as the magnetic powder, any one of nitrile rubber, hydrogenated nitrile rubber, acrylic rubber, butyl rubber and fluororubber can be used.

As the rare earth magnetic powder, one that is comprised of neodymium (Nd), iron (Fe) and boron (B), or one that is comprised of samarium (Sm), iron (Fe) and nitrogen (N) can be used.

In all of the cases where the rare earth magnetic powder comprised of a combination of neodymium (Nd), iron (Fe) and boron (B) is used and where the rare earth magnetic powder comprised of a combination of samarium (Sm), iron (Fe) and nitrogen (N) is used, a compounding ratio of the rare earth magnetic powder to the rubber material is preferably in the range of from 70 to 98% by weight ratio. When the rare earth magnetic powder is compounded less than 70% (by weight) relative to the rubber material, a magnetic force of a produced magnetic encoder becomes unfavorably insufficient; on the contrary, when it is compounded more than 98% (by weight), unvulcanized rubber becomes unfavorably hard, resulting in poor workability.

As the rare earth magnetic powder comprised of a combination of neodymium (Nd), iron (Fe) and boron (B), for instance, one having a composition, Nd₂Fe₁₄B, can be adopted. Furthermore, as the rare earth magnetic powder comprised of a combination of samarium (Sm), iron (Fe) and nitrogen (N), for instance, one having a composition, Sm₂Fe₁₇Nₓ (here, x is an arbitrary value up to 3), can be adopted. Adoption of one of these, while maintaining excellent magnetic characteristics, together with the before described compounding ratio relative to the rubber material, allows exhibiting excellent formability and kneading property.

Rare earth magnetic powders that are obtained as composites between the above-mentioned rare earth magnetic powders and Fe₃B, αFe or so on as a soft magnetic phase can also exhibit the similar action and effect; accordingly, these can be used as the rare earth magnetic powder.

Furthermore, the other rare earth magnetic powders comprised of a combination of neodymium (Nd), iron (Fe) and boron (B) having a composition different from one described above and a combination of samarium (Sm), iron (Fe) and nitrogen (N) having a composition different from one described above can be also adopted provided that they are used together with the before described compounding ratio relative to the rubber material, and excellent formability and kneading property can be exhibited, while the excellent magnetic characteristics are maintained.

With respect to the reinforcement ring 1 that supports the magnetic rubber ring 2, plates made of magnetic materials such as cold rolled steel plate (SPCC), SUS 430 and so on can be preferably used. These are advantageous because these can make a magnetic field wider and increase a magnetic force.

In the magnetic encoder according to the invention, a surface of the magnetic rubber ring 2 may be covered with a protective film. Since the magnetic powder made of a rare earth element is used, covering a surface of the magnetic rubber ring 2 with the protective film is effective in view of inhibiting in advance the rare earth magnetic powder from rusting. As the protective film, an acrylic paint, urethane paint, epoxy paint and phenolic paint can be adopted.

In order to endow the magnetic rubber with conductivity, the rubber material is mixed with a conductive material (conductive carbon, metal powder and so on) and a surface of a magnetic rubber ring 2 formed therefrom may be electroplated to form a protective film.

At this time, as the metal plating, nickel, tin, or nickel alloys can be advantageously used. On a surface of the electroplating, a coating made of a synthetic resin can be applied.

According to the invention, in comparison with the existing magnetic encoder in which the ferrite powder is used as the magnetic powder, a higher magnetic force can be obtained; accordingly, a magnetic encoder having a high pulse-generating capability can be provided.

According to the invention, in order to form a magnetic rubber ring 2 that constitutes a magnetic encoder, rare earth magnetic powder comprising neodymium (Nd), iron (Fe) and boron (B) are combined, or rare earth magnetic powder comprising samarium (Sm), iron (Fe) and nitrogen (N) are combined is mixed with the rubber material. Thereby, since a high magnetic force can be exhibited, a magnetic encoder can be made smaller in size and lighter in weight, and measurement accuracy thereof can be drastically improved.

Furthermore, in the magnetic encoder of the present invention, several kinds of rare earth magnetic powders are selected and blended together, the formability, in particular, the kneading property can be improved. That is, the magnetic encoder according to the invention is excellent also in the formability.

The magnetic encoder according to the invention is a multi-pole magnetic encoder in which an S pole and an N pole are alternately and radially magnetized and the number of poles is large; however, a magnetic force of one pole can be maintained large. Accordingly, a magnetic force can be securely and assuredly detected with a sensor disposed facing to the magnetic encoder according to the invention.

Since the magnetic encoder according to the invention has a strong magnetic force, a gap between the magnetic encoder and the sensor disposed opposite thereto can be set larger. As a result, assembling tolerance thereof can be set rough.

According to the above, the magnetic encoder can be made smaller in size and lighter in weight, and the magnetic encoders with high productivity can be provided at lower prices.

### BRIEF DESCRIPTION OF DRAWINGS

FIG. 1 is a partially cut out perspective view showing one embodiment of a magnetic encoder according to the present invention;

FIG. 2 is a partially omitted sectional view of another embodiment; and

FIG. 3 is a partially omitted sectional view of still another embodiment.

### DESCRIPTION OF THE PREFERRED EMBODIMENTS

Hereinafter, the preferred embodiment of the present invention will be described with reference to the accompanying drawings.

### Example 1

A nitrile rubber is used as the rubber material. A rare earth magnetic powder made of a combination of neodymium (Nd), iron (Fe) and boron (B), and a rubber chemical that has been used in the manufacture of magnetic encoders are added to the nitrile rubber, and then kneaded together. Thereby an unvulcanized magnetic rubber base (not shown in the drawing) is prepared. A compounding ratio of the rare earth magnetic powder was set at 85% by weight ratio relative to the nitrile rubber. As the rare earth magnetic powder, one having a composition, Nd₂Fe₁₄B, is used.

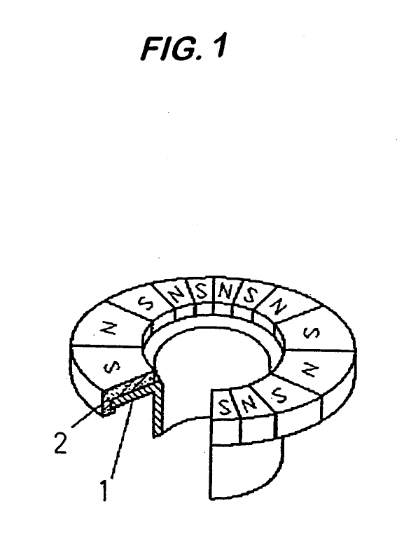

The magnetic rubber base, with an adhesive interposed with a reinforcement ring 1, was heated and compressed by use of a mold and thereby vulcanized, molded and adhered, and thereby a magnetic rubber ring 2 is formed as shown in FIG. 1. The molded magnetic rubber ring 2 had a thickness of 1.0 mm and a width of 6.0 mm.

Subsequently, the magnetic rubber ring 2 was magnetized radially with an S pole and an N pole alternated, and thereby a magnetic encoder according to the invention was obtained (hereinafter the magnetic encoder according to the invention obtained in Example 1 is referred to as “effected product 1”).

In the magnetic encoder according to the invention molded as shown in FIG. 1, the magnetic rubber ring 2 directing to an axial direction is engaged with an inner circumference side member (in FIG. 1, one that is disposed in a hole portion present in the center of the reinforcement ring 1 and not shown in the drawing) and thereby used as a single body.

### Example 2

Except that a combination of samarium (Sm), iron (Fe) and nitrogen (N) is used as a rare earth magnetic powder, similarly to Example 1, a magnetic encoder according to the invention (effected product 2) was obtained. As the rare earth magnetic powder, one that has a composition, Sm₂Fe₁₇N_{2.7}, was used.

### Comparative Example 1

Except that in Example 1, in place of the rare earth magnetic powder, ferrite powder was used, similarly to Example 1, an existing magnetic encoder (comparative product 1) was formed.

Effected products 1 and 2 and Comparative product 1 were measured of the magnetic force characteristics with a B-H curve tracer. Furthermore, with a Hall sensor, the magnetic flux densities of the respective magnetic poles were measured, and therefrom an average magnetic flux density along an encoder circumference was calculated. Results are as follows.

| | Effected | Effected | Comparative |
|---|---|---|---|
| | product 1 | product 2 | product 1 |
| | (Nd₂Fe₁₄B) | (Sm₂Fe₁₇N_{2.7}) | (Ferrite) |
| Magnetic force | 19.5 | 16.0 | 8.0 |
| characteristics | | | |
| ((BH)ₘₐₓ/kJ · m³) | | | |
| Average magnetic flux | 27.2 | 29.5 | 17.7 |
| density along magnetic | | | |
| encoder circumference | | | |
| (mT) | | | |

There was no particular difference in the kneading workability and the formability in the respective manufacturing steps of the effected products 1 and 2 and comparative product 1.

On the other hand, it was confirmed that the effected products 1 and 2 have magnetic force stronger than that of the comparative product 1.

In Examples 1 and 2, a method in which the magnetic rubber base in which unvulcanized rubber and rare earth magnetic powder are mixed was vulcanized molded and adhered to the reinforcement ring 1, and thereby the magnetic rubber ring 2 was molded was shown; however, other forming method can be adopted.

For instance, after a sheet of a magnetic rubber base in which rare earth magnetic powder is mixed is cut out in a ring shape, this is vulcanized and adhered to a reinforcement ring 1, and thereby forming in one body. In this case, it is advantageous in that the workability is excellent in the magnetizing step.

Other than this, with a liquid rubber material such as urethane rubber, nitrile rubber, chloroprene rubber, styrene butadiene rubber, polybutene rubber, silicone rubber or SIFEL as a binder, thereto the rare earth magnetic powder is mixed by an amount corresponding to the above-mentioned compounding ratio, this is coated on the reinforcement ring 1 by means of coating, spraying or screen-printing, and thereby the magnetic rubber ring 2 may be formed.

Furthermore, in anyone of liquid synthetic resin materials such as urethane, epoxy, phenol, silicone, ethylene vinyl acetate, acryl, urea and polyester, the rare earth magnetic powder is mixed by an amount corresponding to the above-mentioned compounding ratio, this is coated on the reinforcement ring 1 by means of coating, spraying or screen-printing, and this may be used in place of the magnetic rubber ring 2.

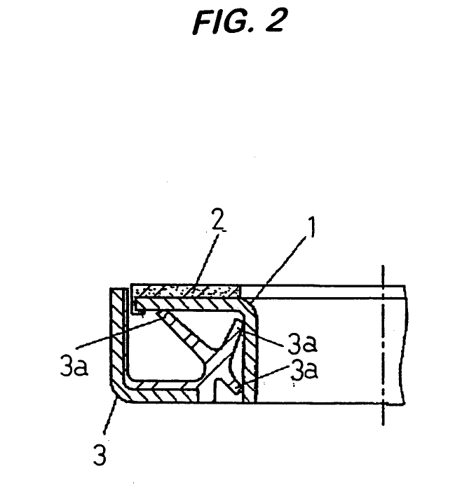

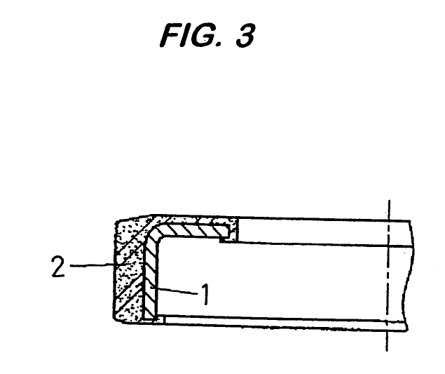

In Examples 1 and 2, the magnetic encoder in which the magnetic rubber ring 2 facing an axial direction was engaged with an inner circumference side member (not shown in the drawing) and integrated therewith was explained. However, the magnetic encoder according to the invention can be formed into a combination seal structure in which a seal member 3 provided with seal lips 3a is combined with a magnetic encoder as shown in FIG. 2. Still furthermore, a radial magnetic encoder structure in which a magnetic rubber ring 2 directs in a radial direction can be adopted as shown in FIG. 3.

In the foregoing, preferable embodiments of the present invention are described. But the present invention is not limited to the above-described embodiments and can be carried out in various modes within the technical scope described in the claims.

1. A magnetic encoder for use in a wheel bearing that forms a pulse train by means of a magnetic force and generates a code, wherein the magnetic encoder is formed by radially magnetizing a magnetic rubber ring with alternate S poles and N poles, wherein said magnetic rubber ring is formed by mixing a rubber material and a magnetic powder, and wherein said magnetic powder is a rare earth magnetic powder.

2. The magnetic encoder as set forth in claim 1, wherein the rare earth magnetic powder comprises neodymium (Nd), iron (Fe) and boron (B).

3. The magnetic encoder as set forth in claim 1, wherein the rare earth magnetic powder comprises samarium (Sm), iron (Fe) and nitrogen (N).

4. The magnetic encoder as set forth in claim 1, wherein said magnetic rubber ring has a thickness in a range from 0.2 to 2.0 mm.

5. A magnetic encoder for use in a wheel bearing that forms a pulse train by means of a magnetic force and generates a code, wherein the magnetic encoder is formed by radially magnetizing a magnetic rubber ring with alternate S poles and N poles, and wherein said magnetic rubber ring is formed by vulcanizing and adhering a magnetic rubber base, in which unvulcanized rubber and rare earth magnetic powder are mixed, to a reinforcement ring.

6. The magnetic encoder as set forth in claim 5, wherein the rare earth magnetic powder comprises neodymium (Nd), iron (Fe) and boron (B).

7. The magnetic encoder as set forth in claim 5, wherein the rare earth magnetic powder comprises samarium (Sm), iron (Fe) and nitrogen (N).

8. The magnetic encoder as set forth in claim 5, wherein said magnetic rubber ring that is vulcanized, molded and adhered to said reinforcement ring has a thickness in a range from 0.2 to 2.0 mm.

9. The magnetic encoder as set forth in claim 2, wherein said magnetic rubber ring has a thickness in a range from 0.2 to 2.0 mm.

10. The magnetic encoder as set forth in claim 3, wherein said magnetic rubber ring has a thickness in a range from 0.2 to 2.0 mm.

11. The magnetic encoder as set forth in claim 6, wherein said magnetic rubber ring that is vulcanized, molded and adhered to said reinforcement ring has a thickness in a range from 0.2 to 2.0 mm.

12. The magnetic encoder as set forth in claim 7, wherein said magnetic rubber ring that is vulcanized, molded and adhered to said reinforcement ring has a thickness in a range from 0.2 to 2.0 mm.
